(19) United States
(12) Patent Application Publication
(10) Pub. No.: US 2025/0391482 A1
(43) Pub. Date: Dec. 25, 2025

(54) NONVOLATILE MEMORY DEVICES HAVING IMPROVED DATA RELIABILITY AND METHODS OF OPERATING THE SAME

(71) Applicant: Samsung Electronics Co., Ltd., Suwon-si (KR)

(72) Inventors: Garam Kim, Suwon-si (KR); Sangwon Park, Suwon-si (KR); Sangwon Kim, Suwon-si (KR); Ilhan Park, Suwon-si (KR); Taeyun Lee, Suwon-si (KR)

(21) Appl. No.: 19/206,294

(22) Filed: May 13, 2025

(30) Foreign Application Priority Data
Jun. 20, 2024 (KR) 10-2024-0080591
Aug. 30, 2024 (KR) 10-2024-0117941

(51) Int. Cl. G11C 16/34; G11C 16/04

(52) U.S. Cl. CPC G11C 16/3427; G11C 16/0483

(57) ABSTRACT

A memory device includes an array of memory cells having a plurality of cell strings therein electrically coupled to a ground select line (GSL) region. This region includes: a plurality of rows of ground select transistors having programmable threshold voltages, a first row of dummy memory cells extending immediately adjacent a first one of the plurality of rows of ground select transistors and programmed to have threshold voltages within a first threshold voltage distribution, and a second row of dummy memory cells extending immediately adjacent a second one of the plurality of rows of ground select transistors. The second row of dummy memory cells are programmed to have threshold voltages within a second threshold voltage distribution, which has a center threshold voltage that is spaced apart from a center threshold voltage within the first threshold voltage distribution, on a threshold voltage scale.

### REFERENCE TO PRIORITY APPLICATION

This application claims priority under 35 U.S.C. § 119 to Korean Patent Application No. 10-2024-0080591, filed Jun. 20, 2024, and Korean Patent Application No. 10-2024-0117941, filed Aug. 30, 2024, the disclosures of which are hereby incorporated herein by reference.

### BACKGROUND

The inventive concept relates to memory devices and, more particularly, to memory devices having improved data reliability and methods of operating the same.

A non-volatile memory device may include a plurality of memory cells that store data in a non-volatile manner. One example of a non-volatile memory device includes a flash memory device, which may be used in cell phones, digital cameras, personal digital assistants (PDAs), portable computer devices, stationary computer devices, and other devices.

To increase the capacity of memory devices, three-dimensional memory devices having vertical channel structures that extend vertically on a substrate have been successfully developed. In addition, to improve the integration of memory devices, methods, such as increasing the number of word lines stacked vertically on the top of the substrate or removing dummy holes formed in the memory device, have been proposed.

However, as the integration of memory devices increases, interference between word lines, string select lines, and ground select lines may increase, thereby deteriorating data reliability. In addition, in response to a plurality of cell strings, the ground select lines need to be physically or electrically separated. When the ground select lines are physically separated, integration may be deteriorated due to the formation of dummy holes, and when the ground select lines are electrically separated, the characteristics of the memory cells may be degraded because of hot carrier injection (HCI) between various closely spaced-apart lines.

### SUMMARY

The inventive concept provides memory devices capable of improving data reliability while improving integration and operation thereof.

According to an aspect of the inventive concept, there is provided a memory device including a memory cell array including a cell block including a plurality of cell strings, wherein the cell block includes a ground select line (GSL) region to electrically separate the plurality of cell strings, and control logic for controlling program and read operations for the memory cell array, wherein the GSL region includes a plurality of ground select lines where a plurality of ground select transistors are connected and threshold voltages of the plurality of ground select transistors are programmed based on coding, and first and second dummy lines each arranged adjacent to at least one ground select line, wherein the threshold voltage distribution of the dummy cells connected to the first dummy line is different from the threshold voltage distribution of the dummy cells connected to the second dummy line.

According to another aspect of the inventive concept, there is provided a memory device including a memory cell array including a cell block including a plurality of cell strings, wherein the cell block includes a common source line, a GSL region for electrically separating the plurality of cell strings, and normal word lines to which memory cells where data is programmed are connected, which are sequentially arranged in a vertical direction, and control logic for controlling program and read operations for the memory cell array, wherein the GSL region includes a plurality of ground select lines, each of which is connected to a plurality of ground select transistors, wherein the plurality of ground select transistors are programmed to have a first threshold voltage distribution and a second threshold voltage distribution, and a plurality of dummy lines, each of which is connected to a plurality of dummy cells, wherein the plurality of dummy cells have one threshold voltage distribution, and the threshold voltage distribution of dummy cells connected to some dummy lines and the threshold voltage distribution of dummy cells connected to the other dummy lines have different levels.

According to another aspect of the inventive concept, there is provided a memory device including a memory cell array including a cell block including a plurality of cell strings, wherein the cell block includes a common source line, a GSL region for electrically separating the plurality of cell strings, and normal word lines to which memory cells where data is programmed are connected, which are sequentially arranged in a vertical direction, and control logic for controlling program and read operations for the memory cell array, wherein the GSL region includes a plurality of ground select lines where a plurality of ground select transistors are connected and threshold voltages of the plurality of ground select transistors are programmed based on coding, and at least one first dummy line arranged at the bottom of the GSL region and adjacent to the common source line, at least one second dummy line arranged between the plurality of ground select lines, and at least one third dummy line arranged at the top of the GSL region and adjacent to the normal word lines.

According to a further aspect of the inventive concept, a memory device is provided that includes an array of memory cells having a plurality of cell strings therein that are electrically coupled to an enhanced performance ground select line (GSL) region. This GSL region includes a plurality of rows of ground select transistors, which have programmable threshold voltages and are electrically coupled to a corresponding plurality of ground select lines. In addition, a first row of dummy memory cells are provided, which extend immediately adjacent a first one of the plurality of rows of ground select transistors, and are programmed to have threshold voltages within a first threshold voltage distribution. A second row of dummy memory cells are also provided, which extend immediately adjacent a second one of the plurality of rows of ground select transistors, and are programmed to have threshold voltages within a second threshold voltage distribution, which has a center threshold voltage that is spaced apart from a center threshold voltage within the first threshold voltage distribution, on a threshold voltage scale.

According to still further aspects of the inventive concept, a memory device is provided that includes at least one vertical NAND-type string of non-volatile memory cells, on a substrate, along with a ground select line (GSL) region that is electrically connected to a source terminal of a lowermost one of the non-volatile memory cells within the vertical NAND-type string, and extends between the vertical NAND-type string of non-volatile memory cells and the substrate. This GSL region includes at least one totem pole arrangement of: (i) a ground select transistor programmed to a coded threshold voltage, which corresponds to one of an erased state (e.g., Vth (low)) and a programmed state (e.g., Vth (high)) associated with the non-volatile memory cells within the vertical NAND-type string, and (ii) a dummy memory cell programmed to an intermediate threshold voltage that is greater than a threshold voltage associated with the erased state and less than a threshold voltage associated with the programmed state.

### BRIEF DESCRIPTION OF THE DRAWINGS

Embodiments will be more clearly understood from the following detailed description taken in conjunction with the accompanying drawings in which:

FIG. 1 is a block diagram of a memory system according to an embodiment;

FIGS. 2A and 2B are cross-sectional views of a cell block with a vertical dummy hole and a cell block that omits a dummy hole;

FIG. 3 is a diagram illustrating a coding operation for ground select lines in a ground select line (GSL) region;

FIG. 4 is a diagram of a cell block of a memory device, according to an embodiment;

FIG. 5 is a block diagram of a memory device according to an embodiment;

FIGS. 6A to 8 are diagrams illustrating implementation examples of a cell block, according to some embodiments;

FIGS. 9A to 10 are diagrams showing the threshold voltage distribution and the voltage level of a dummy line;

FIG. 11 is a diagram showing the threshold voltage distribution of a dummy line, according to an embodiment;

FIG. 12 is a diagram showing the threshold voltage distribution of various lines in a GSL region, according to another embodiment; and

FIG. 13 is a block diagram of a solid state drive (SSD) system to which a memory device is applied, according to some embodiments.

### DETAILED DESCRIPTION OF EMBODIMENTS

Hereinafter, embodiments are described in detail with reference to the attached drawings.

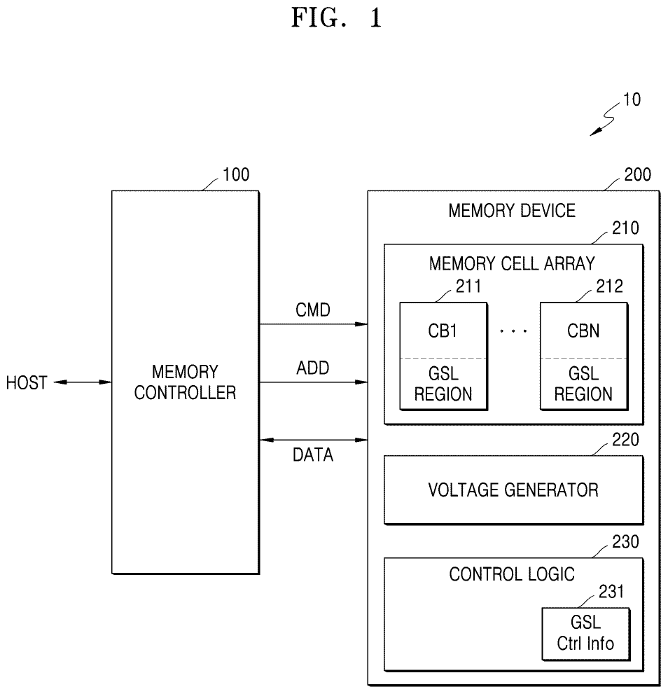

Referring to FIG. 1, a memory system 10 may include a memory controller 100 and a memory device 200, wherein the memory device 200 may include a memory cell array 210, a voltage generator 220, and control logic 230. Although not shown in FIG. 1, the memory device 200 may further include other components related to a memory operation, such as data program/read/erase operation. As an example, the memory device 200 may further include a page buffer connected to the memory cell array 210 through bit lines.

According to an embodiment, the memory device 200 may include a non-volatile memory device, such as a NAND flash memory, vertical NAND flash memory, resistive random-access memory, phase-change memory, and magnetoresistive random-access memory. In some embodiments, the memory device 200 or the memory system 10 may be implemented as an embedded memory built into an electronic device or as an external memory removable from the electronic device. In some embodiments, the memory system 200 or the memory system 10 may be implemented in various forms, such as an embedded universal flash storage (UFS) memory device, an embedded multimedia card (eMMC), a solid state drive (SSD), a UFS memory card, a compact flash (CF), a secure digital (SD), a micro-secure digital (Micro-SD), a mini secure digital (mini-SD), an extreme digital (xD), or a memory stick.

The memory controller 100 may control the memory device 200 to read data stored in the memory device 200 or to write (or program) data to the memory device 200, in response to a write/read request from a host. Specifically, the memory controller 100 may control program, read, and erase operations for the memory device 200 by providing an address ADD and a command CMD to the memory device 200.

Additionally, data DATA to be written to the memory device 200 and data DATA read from the memory device 200 may be exchanged between the memory controller 100 and the memory device 200.

The memory cell array 210 may include a plurality of cell blocks CB1 to CBN. When the memory device 200 corresponds to a vertical NAND flash memory device, each of the cell blocks CB1 to CBN may include a plurality of cell strings. As an example, the plurality of cell strings may be arranged in correspondence with one bit line, and during a data program/read operation, a selected cell string among the plurality of cell strings may be electrically connected to the bit line.

According to an embodiment, each cell block may include a ground select line (GSL) region in which a plurality of ground select lines GSL are arranged. A plurality of ground select transistors may be connected to each of the ground select lines GSL, wherein each of the ground select transistors may be programmed to a certain threshold voltage. In an embodiment, the control logic 230 may include a storage circuit 231 storing GSL control information. For example, the storage circuit 231 may include certain storage devices which store information in a non-volatile manner, such as a fuse circuit and an anti-fuse circuit. A coding operation for the plurality of ground select transistors in the GSL region may be controlled based on the GSL control information. As an operation example, the GSL control information may be read and provided to the memory controller 100, wherein the memory controller 100 may control the coding operation based on the GSL control information.

Alternatively, during the process of manufacturing the memory device 200, the GSL control information may be implemented to be stored in a storage circuit external to the control logic 230. Alternatively, in another embodiment, the GSL control information may be stored outside the memory device 200 within the memory system 10. As an example, the GSL control information may be stored in the memory controller 100.

The coding operation may include an operation of programming the threshold voltage of the ground select transistors, wherein the ground select transistor on which coding is performed may be referred to as a coded ground select transistor. Additionally, each cell block may further include one or more normal ground select transistors arranged outside the GSL region. In describing the following embodiments, the ground select transistor may refer to a coded ground select transistor, included in the GSL region, on which coding is performed. Alternatively, the ground select transistor may be defined as including the coded ground select transistor and the normal ground select transistor.

According to an embodiment, the GSL region may include the plurality of ground select lines GSL and one or more dummy word lines (hereinafter referred to as dummy lines). The dummy lines may be arranged to improve channel potential boundary characteristics between a plurality of lines provided in a cell block. For example, the GSL region may be arranged between a normal word line connected to memory cells where data is programmed and a normal ground select transistor (or common source line). The dummy lines, according to an embodiment, may be arranged at various locations within the GSL region to improve hot carrier injection (HCI) characteristics between various lines or retention characteristics of transistors connected to each line.

In an embodiment, assuming a structure in which the common source line, the normal ground select line, the GSL region, and the plurality of word lines are sequentially arranged on a substrate in a vertical direction, the dummy line at the bottom of the GSL region may be arranged adjacent to the common source line (or normal ground select line). Alternatively, the dummy line may be arranged adjacent to the plurality of word lines as the dummy line is arranged at the top of the GSL region. Alternatively, the dummy line may be arranged at any position between the ground select lines GSL. Alternatively, when the GSL region includes two or more dummy lines, the dummy lines may be arranged continuously or discontinuously.

When the GSL region includes a plurality of dummy lines, each dummy line may be arranged at any position within the GSL region. As an example, some dummy lines may be arranged adjacent to the common source line, and the other dummy lines may be arranged adjacent to the normal word line. Alternatively, some dummy lines may be arranged adjacent to the common source line or the normal word line, and the other dummy lines may be arranged between any ground select lines GSL. Alternatively, two or more dummy lines may be arranged between any ground select lines GSL, without the dummy lines being arranged at the top or the bottom of the GSL region. Embodiments are not limited to the arrangement of dummy lines described above. Other numbers of dummy lines may be arranged at various positions in the GSL region.

According to an embodiment, in the GSL region arranged to electrically isolate the ground select lines for the plurality of cell strings (or string select lines), the threshold voltage characteristics of the ground select lines may be improved, thereby improving the electrical separation characteristics. In addition, the interference between various lines of the cell block may be reduced, thereby improving data reliability.

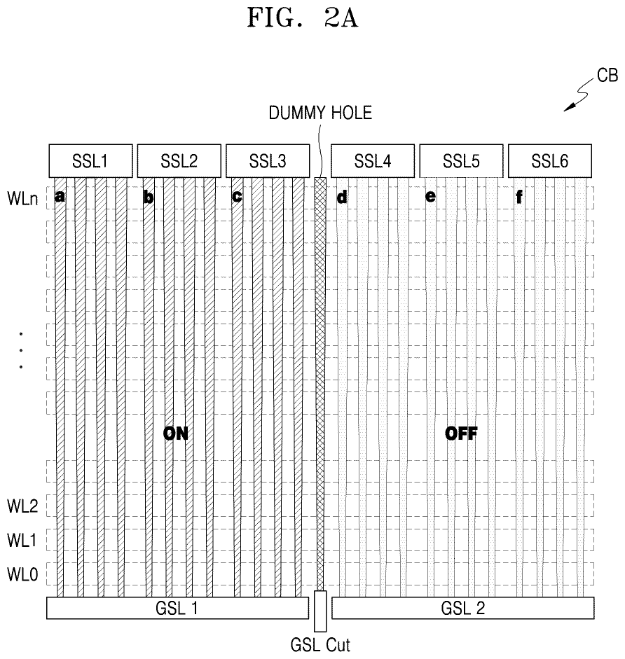

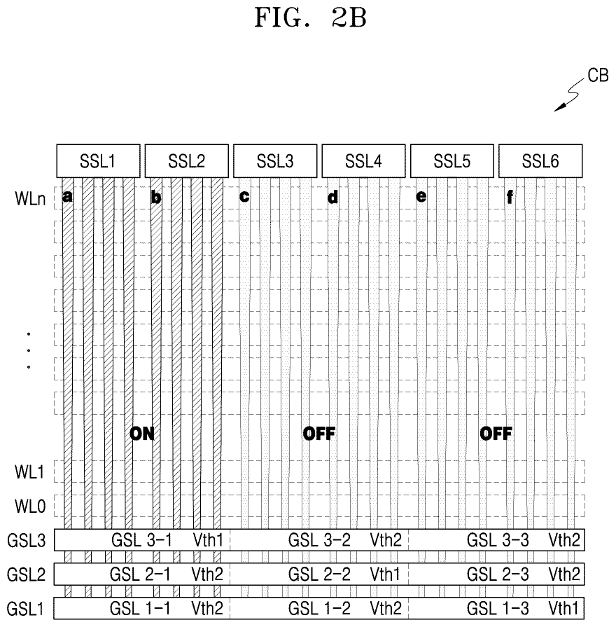

FIGS. 2A and 2B are cross-sectional views of a cell block with a dummy hole and a cell block without a dummy hole. Referring to FIG. 2A, a GSL cut is used to physically separate ground select lines. At least one dummy hole may be formed in a cell block CB to enable formation of the GSL cut (e.g., via etching). Each cell string may be connected to a corresponding cell string line. In FIG. 2A, first to sixth string select lines SSL1 to SSL6 are illustrated. Since the first to sixth string select lines SSL1 to SSL6 are physically separated, string select transistors (not shown) connected to the first to sixth string select lines SSL1 to SSL6 may be controlled separately from each other.

As an example, the first ground select line GSL1 and the second ground select line GSL2 may be physically separated from each other. The first ground select line GSL1 may be arranged for the first to third string select lines SSL1 to SSL3, and the second ground select line GSL2 may be arranged for the fourth to sixth string select lines SSL4 to SSL6. When the first string select line SSL1 is selected, the ground select transistors connected to the first ground select line GSL1 may be turned on, while the ground select transistors connected to the second ground select line GSL2 may be turned off.

A plurality of cell strings may be connected to each string select line. Additionally, the cell strings (e.g., cell strings a to f) connected to the first to sixth string select lines SSL1 to SSL6 may be commonly connected to the same bit line (not shown). For example, when the first cell string a is selected from among the cell strings a to f of the first to sixth string select lines SSL1 to SSL6, the first cell string a may be electrically connected to the bit line as the string select transistors connected to the first string select line SSL1 are turned on, while the other cell strings may be cut off from electrical connection to the bit line.

As the ground select transistors connected to the first ground select line GSL1 are turned on, the ground select transistors provided to the unselected cell strings b and c may also be turned on. However, since the string select transistors of the unselected cell strings b and c are turned off as described above, the program/read operation may be prevented from being performed on the unselected cell strings b and c.

To improve memory operation characteristics, such as the program/read operation of the cell block CB, it is advantageous to physically separate the ground select lines more. Accordingly, although one dummy hole is illustrated in FIG. 2A, a greater number of dummy holes may be formed in the cell block CB. For example, when two dummy holes are formed in the cell block CB, three physically separate ground select lines may be arranged for the first to sixth string select lines SSL1 to SSL6. However, as described above, when the number of dummy holes increases, the integration of the cell block CB may deteriorate.

Referring to FIG. 2B, without the dummy hole, the GSL region is arranged for electrical separation of the ground select lines. In FIG. 2B, corresponding to the first to sixth string select lines SSL1 to SSL6, the GSL region includes the first to third ground select lines GSL1 to GSL3. In FIG. 2B, each ground select line is shown with a dashed line to include three regions, but this is to conceptually illustrate the electrical separation characteristics. Physically, each of the first to third ground select lines GSL1 to GSL3 may correspond to a line commonly arranged in the first to sixth string select lines SSL1 to SSL6.

The ground select transistors connected to each of the first to third ground select lines GSL1 to GSL3 may be programmed to a certain threshold voltage. As an example, with respect to the third ground select line GSL3, ground select transistors of a third-1 region GSL3-1 corresponding to the first and second string select lines SSL1 and SSL2 may be programmed to a first threshold voltage Vth1. On the other hand, ground select transistors of a third-2 region GSL3-2 and a third-3 region GSL3-3 corresponding to the third to sixth string select lines SSL3 to SSL6 may be programmed to a second threshold voltage Vth2, the voltage Vth2 being greater than the first threshold voltage Vth1.

Similarly, with respect to the second ground select line GSL2, ground select transistors of a second-2 region GSL2-2 corresponding to the third and fourth string select lines SSL3 and SSL4 may be programmed to the first threshold voltage Vth1. On the other hand, ground select transistors of a second-1 region GSL2-1 and a second-3 region GSL2-3 corresponding to the first and second string select lines SSL1 and SSL2 and the fifth and sixth string select lines SSL5 and SSL6, respectively, may be programmed to the second threshold voltage Vth2. In addition, with respect to the first ground select line GSL1, ground select transistors of the first-3 region GSL1-3 corresponding to the fifth and sixth string select lines SSL5 and SSL6 may be programmed to the first threshold voltage Vth1, while ground select transistors of the first-1 region GSL1-1 and the first-2 region GSL1-2 corresponding to the first to fourth string select lines SSL1 to SSL4 may be programmed to the second threshold voltage Vth2.

When any one of the first and second string select lines SSL1 and SSL2 is selected, a ground select voltage having a level between the first threshold voltage Vth1 and the second threshold voltage Vth2 may be provided to the third ground select line GSL3. Thus, the ground select transistors of the third-1 region GSL3-1 may be turned on, while the ground select transistors of the third-2 region GSL3-2 and the third-3 region GSL3-3 may be turned off. Accordingly, the cell strings of the third to sixth string select lines SSL3 to SSL6 may be electrically separated from the common source line.

According to the electrical separation structure shown in FIG. 2B, when one of the third and fourth string select lines SSL3 and SSL4 is selected, a ground select voltage having a level between the first threshold voltage Vth1 and the second threshold voltage Vth2 may be provided to the second ground select line GSL2, thereby turning on the ground select transistors of the second-2 region GSL2-2. In addition, when any one of the fifth and sixth string select lines SSL5 and SSL6 is selected, a ground select voltage having a level between the first threshold voltage Vth1 and the second threshold voltage Vth2 may be provided to the first ground select line GSL1, thereby turning on the ground select transistors of the first-3 region GSL1-3.

According to the structure shown in FIG. 2B, a plurality of ground select transistors may be arranged vertically in one cell string and may be arranged between a normal word line (e.g., WL0) and a common source line (not shown). In this case, all of the ground select transistors may be controlled to be turned on in a selected cell string, while at least one of the ground select transistors may be controlled to be turned off in an unselected cell string.

In FIG. 2B, three ground select lines are arranged for the first to sixth string select lines SSL1 to SSL6. Accordingly, the ground select lines are electrically separated into groups of two string select lines. However, the above-mentioned electrical separation may be implemented in various ways, and as an example, other numbers of ground select lines may be provided in the cell block CB. For example, when two ground select lines are arranged in the cell block CB, the ground select lines may be electrically separated into groups of three string select lines. Alternatively, when six ground select lines are arranged in the cell block CB, the ground select lines may be electrically separated into groups associated with a corresponding single string select line.

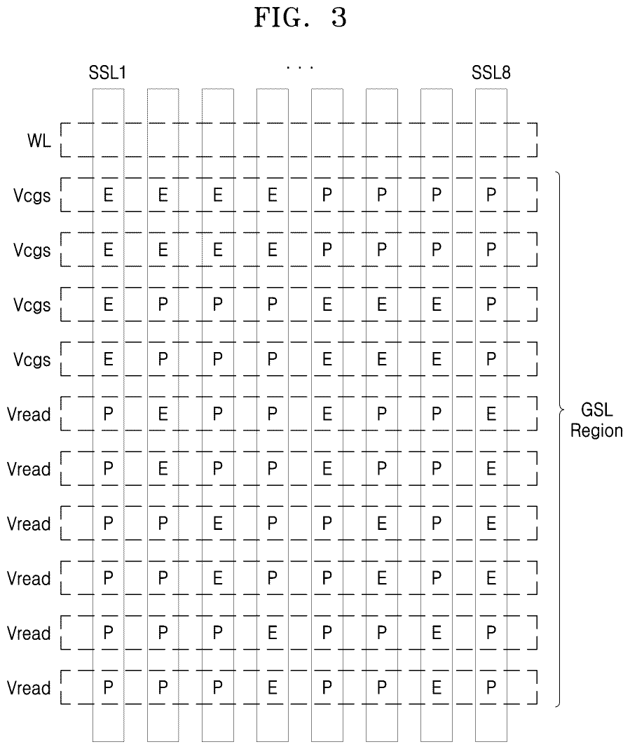

FIG. 3 is a diagram illustrating a coding operation for ground select lines in a GSL region. As shown in FIG. 3, the GSL region may include more ground select lines GSL (e.g., 10) than the string select lines (e.g., 8), wherein each of the ground select transistors may have a first threshold voltage or a second threshold voltage. For example, in FIG. 3, the first threshold voltage is illustrated as an erase state E, and the second threshold voltage is illustrated as a program state P. In an embodiment shown in FIG. 2B, one ground select transistor among the plurality of ground select transistors included in one cell string has the first threshold voltage Vth1. However, in an embodiment shown in FIG. 3, two or more ground select transistors among the plurality of ground select transistors included in one cell string may have the first threshold voltage Vth1 (e.g., as an erase state E).

In FIG. 3, during a memory operation, such as write/read operation of a cell block, a ground select voltage having a first voltage Vcgs or a second voltage Vread may be applied to each of the ground select lines. The first voltage Vegs may have a level between the first threshold voltage and the second threshold voltage. Accordingly, when the first voltage Vcgs is provided to a ground select transistor in the erase state E, the corresponding ground select transistor may be turned on, but when it is provided to a ground select transistor in the program state P, the corresponding ground select transistor may be turned off. In addition, the second voltage Vread may have a level greater than the second threshold voltage. Accordingly, when the second voltage Vread is provided to the ground select transistor in the program state P, the ground select transistor may be turned on.

As shown in FIG. 3, when the first voltage Vcgs and the second voltage Vread are applied, all ground select transistors of the cell string connected to the first string select line SSL1 may be turned on. On the other hand, at least one ground select transistor of cell strings connected to the other second to eighth string select lines SSL2 to SSL8 may be turned off. Accordingly, the ground select line may be electrically separated from the first string select line SSL1 and the other string select lines.

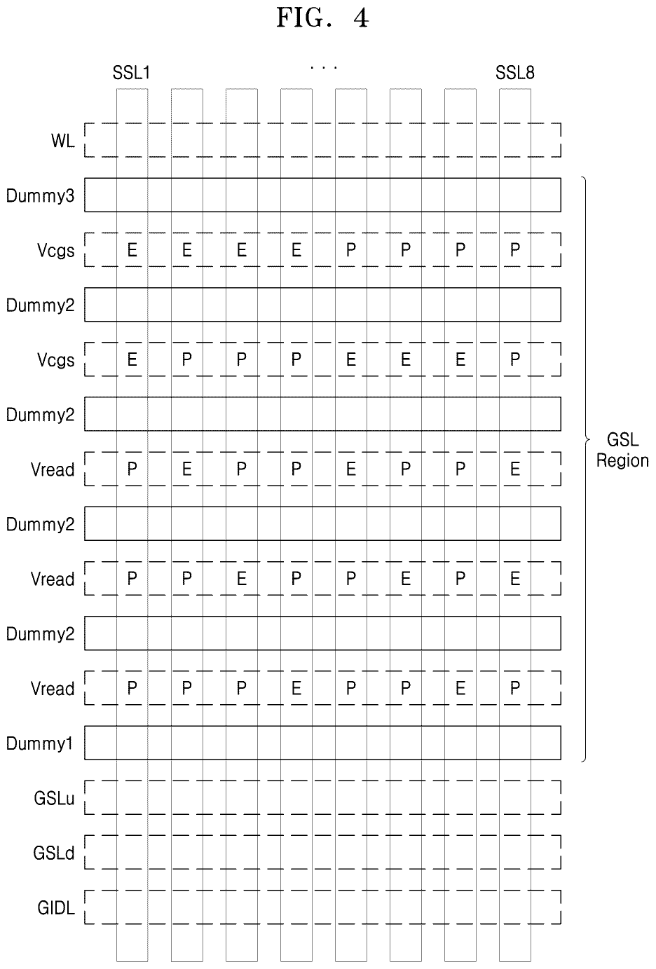

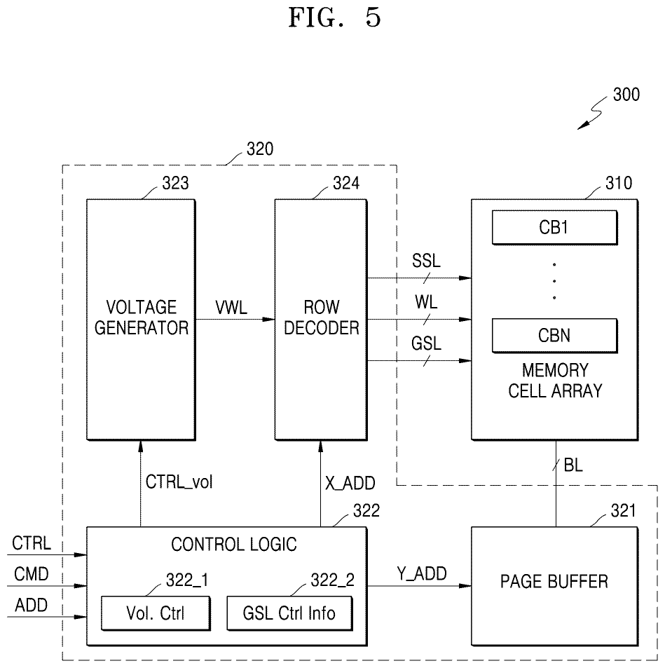

FIG. 4 is a diagram of a cell block of a memory device, according to an embodiment. According to an embodiment, the GSL region may include at least one dummy line along with a plurality of ground select lines. In FIG. 4, the ground select lines of the GSL region are coded in the same or similar manner as shown in FIG. 3. However, embodiments are not limited thereto. The ground select lines of the GSL region may be coded in the same or similar manner as shown in FIG. 2B.

When the cell block has a vertical NAND structure, one or more normal ground select lines GSLu and GSLd may be arranged adjacent to a common source line CSL. In addition, at least one erase control line (or gate induced drain leakage (GIDL) line) may be further arranged. As the normal ground select lines GSLu and GSLd may correspond to non-coded lines, the ground select transistors connected to the normal ground select lines GSLu and GSLd may have an erase state or may be programmed to a preset threshold voltage to have a single threshold voltage distribution. Additionally, the erase control line may be arranged to improve the erase characteristics of the cell block by generating gate induced drain leakage. As an example, an erase voltage may be provided to a channel through transistors connected to the erase control line.

In an embodiment, dummy lines may be arranged at any position in the GSL region. For example, a first dummy line Dummy 1 may be arranged at the bottom of the GSL region and may be arranged adjacent to the normal ground select lines GSLu and GSLd or adjacent to the common source line CSL. Additionally, one or more second dummy lines Dummy 2 may be arranged between the ground select lines within the GSL region. Additionally, a third dummy line Dummy 3 may be arranged at the top of the GSL region and may be arranged adjacent to a normal word line WL. Additionally, during the memory operation, the first voltage Vcgs or the second voltage Vread may be applied to each of the ground select lines. When the ground select voltages are provided as shown in FIG. 4, all ground select transistors of the first cell string connected to the first string select line SSL1 may be turned on. Accordingly, the ground select line may be electrically separated from the first string select line SSL1 and the second to eighth string select lines SSL2 to SSL8.

Assuming that the coded GSLs in the GSL region constitute one ground selection line, the ground selection line is physically disposed in common for the first to eighth string selection lines (SSL1 to SSL8), but the ground selection line can be described as being electrically separated for the first string selection line (SSL1) and the second to eighth string selection lines (SSL2 to SSL8).

The dummy cells corresponding to the first to eighth string select lines SSL1 to SSL8 may be connected to each of the first to third dummy lines Dummy 1 to Dummy 3. Each dummy cell may correspond to a dummy transistor of which a threshold voltage is programmed. Each dummy cell may be programmed to a certain threshold voltage. As an example, when the ground select transistors connected to the ground select line have the erase state E and the program state P, each dummy cell may be programmed to a threshold voltage having a level between the erase state E and the program state P.

In an embodiment, the first to third dummy lines Dummy 1 to Dummy 3 may have different threshold voltage distributions depending on positions thereof. For example, among the first to third dummy lines Dummy 1 to Dummy 3, the program operation may be controlled so that the threshold voltages of dummy cells of some dummy lines have different levels from the threshold voltages of dummy cells of the other dummy lines. Accordingly, the threshold voltage distribution may be formed differently for each of the first to third dummy lines Dummy 1 to Dummy 3. As an example, the threshold voltage distribution may be formed differently depending on whether each dummy line is adjacent to the normal ground select lines GSLu and GSLd or the normal word line WL. Alternatively, depending on the threshold voltage distribution of the adjacent ground select line, the threshold voltage distribution of the corresponding dummy line may be formed differently.

As shown in FIG. 4, according to some embodiments, by arranging one or more dummy lines in the GSL region and programming the plurality of dummy cells connected to each dummy line to a certain threshold voltage, the electrical separation characteristics of the ground select lines for the plurality of string select lines may be improved. For example, the interference due to HCI may occur depending on the difference in the threshold voltage level between the normal word line WL, the ground select line, and the normal ground select lines GSLu and GSLd. As a result, the threshold voltage characteristics of the ground select line on which coding was performed may deteriorate. According to an embodiment, by arranging the dummy line with the threshold voltage distribution between the erase state E and the program state P between various lines, the amount of interference generated in the ground select line may be reduced. For example, in the case of the third dummy line Dummy 3 adjacent to the normal word line WL, when the memory cell connected to the normal word line WL has the program state and the ground select transistors connected to the ground select line adjacent thereto has the erase state E, the amount of interference generated in the ground select transistors may be large. By arranging the third dummy line Dummy 3, the amount of interference generated in the ground select transistors may be reduced.

In an embodiment shown in FIG. 4, dummy lines are arranged at the top, bottom, and intermediate positions within the GSL region, but embodiments are not limited thereto. For example, the dummy lines may be arranged only at the top position, only at the bottom position, or only at the intermediate position within the GSL region. Alternatively, two or more dummy lines may be arranged at the top position within the GSL region or two or more dummy lines may be arranged at the bottom position within the GSL region. Alternatively, the GSL region may be configured so that one or more dummy lines are arranged at the top or bottom position within the GSL region and a dummy line is arranged between the ground select lines.

FIG. 5 is a block diagram of a memory device according to an embodiment. Referring to FIG. 5, a memory device 300 may include a memory cell array 310 and a peripheral circuit 320, wherein the peripheral circuit 320 may include a page buffer 321, control logic 322, a voltage generator 323, and a row decoder 324. Although not shown in FIG. 5, the peripheral circuit 320 may further include other components, such as a data input/output circuit or an input/output interface.

The memory cell array 310 may be connected to the page buffer 321 through bit lines BL and may be connected to the row decoder 324 through word lines. The word lines in a broad sense may include various lines provided in a cell block. As an example, the word lines may include normal word lines WL, string select lines SSL, and ground select lines GSL. Alternatively, the word lines in a narrow sense may refer to normal word lines to which memory cells where data is programmed are connected.

The memory cell array 310 may include a plurality of cell blocks CB1 to CBN, wherein each cell block may include a plurality of cell strings. In addition, as shown in the above-described embodiment, each cell block may include a GSL region, wherein the GSL region may include a plurality of ground select lines and dummy lines and may receive a voltage applied to the ground select lines and dummy lines through the row decoder 324.

Based on a command CMD, an address ADD, and a control signal CTRL, the control logic 322 may output various control signals, to program data into the memory cell array 310 and read data from the memory cell array 310, such as a voltage control signal CTRL_vol, a row address X_ADD, and a column address Y_ADD. The control logic 322 may include a voltage controller 322_1 that controls the level of the voltage generated by the voltage generator 323, and a storage circuit 322_2 that stores GSL control information related to the GSL region coding in the above-described embodiment. In FIG. 5, the voltage controller 322_1 and the storage circuit 322_2 are shown as being provided inside the control logic 322, but the voltage controller 322_1 and/or the storage circuit 322_2 may also be described as being provided outside the control logic 322.

The voltage generator 323 may generate various types of voltages to perform program, read, and erase operations for the memory cell array 310, based on the voltage control signal CTRL_vol. As an example, the voltage generator 323 may generate a word line voltage VWL. In addition, the voltage generator 323 may generate voltage signals provided to the string select lines SSL, the ground select lines GSL, and various lines in the GSL region. The voltage controller 322_1 may control the voltage level for coding of the GSL region provided in the cell blocks CB1 to CBN. For example, under the control by the voltage controller 322_1, the program operation may be performed on the threshold voltage of the ground select transistors of the GSL region provided in each cell block and the threshold voltage of the dummy cells.

Hereinafter, examples of various arrangements of dummy lines in the GSL region, according to some embodiments, are described.

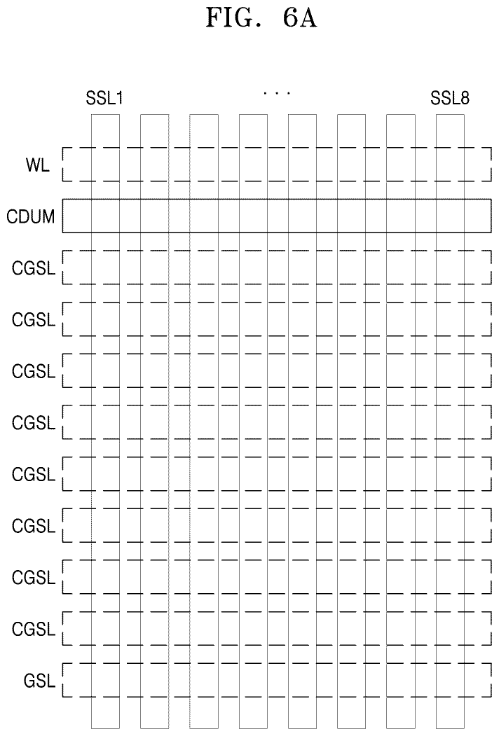

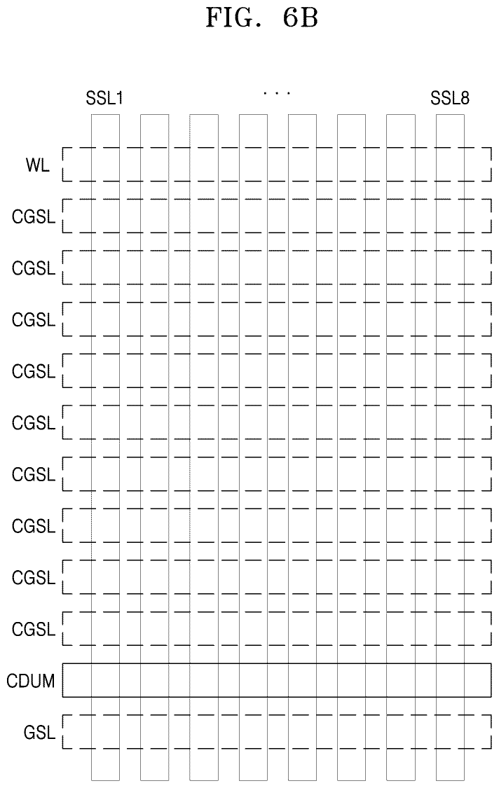

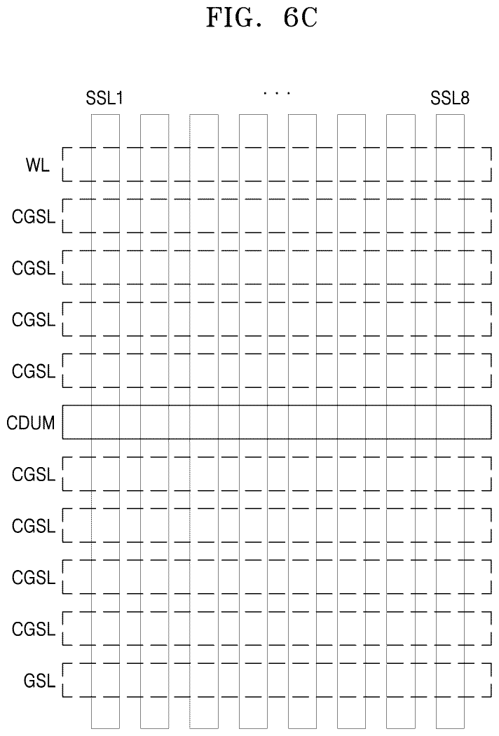

FIGS. 6A to 8 are diagrams illustrating implementation examples of a cell block, according to some embodiments. In some embodiments, the coded ground select line provided in the GSL region may be referred to as a ground select line CGSL, wherein the ground select line CGSL may be distinguished from a normal ground select line GSL arranged outside the GSL region.

As shown in FIGS. 6A, 6B, and 6C, the GSL region may include a plurality of ground select lines CGSL. According to some embodiments, the GSL region may further include one or more dummy lines. As an example, in FIG. 6A, one dummy line CDUM is located at the top of the GSL region, wherein the dummy line CDUM may be located between the normal word line WL and the upper ground select line CGSL. In addition, in FIG. 6B, one dummy line CDUM is located at the bottom the GSL region, wherein the dummy line CDUM may be located between the lower ground select line CGSL and the normal ground select line GSL. Additionally, in FIG. 6C, one dummy line CDUM is located between the ground select lines CGSL within the GSL region.

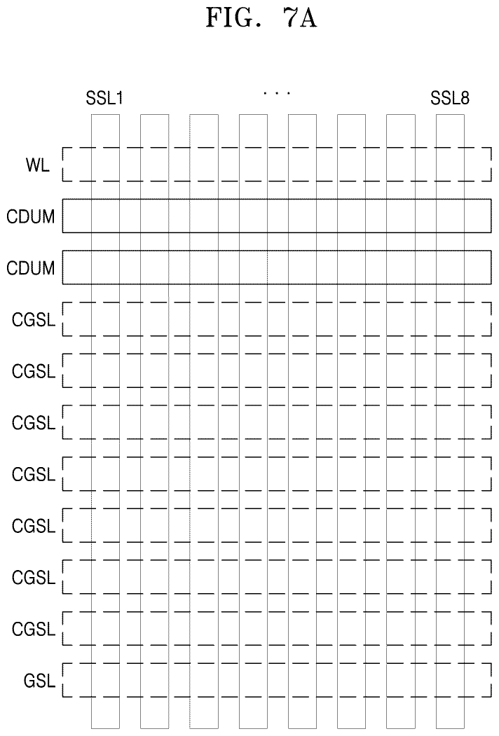

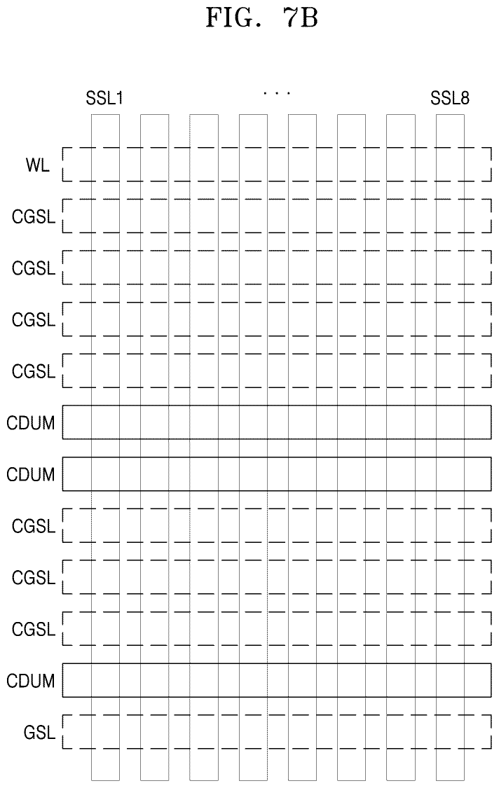

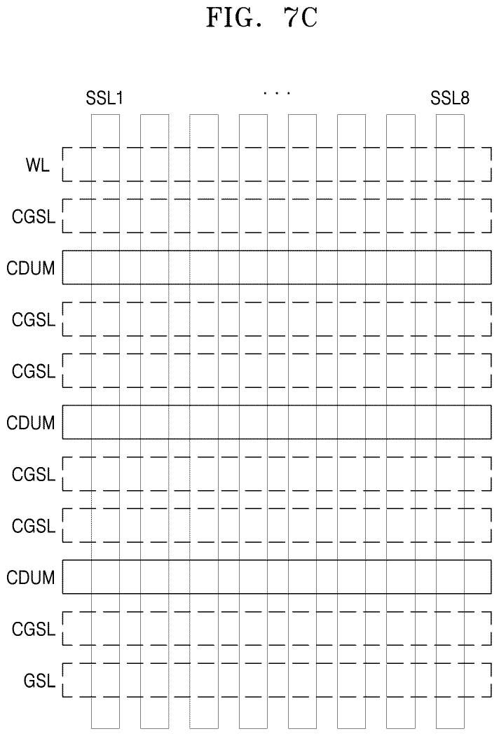

In FIGS. 7A, 7B, and 7C, the GSL region includes two or more dummy lines.

As an example, in FIG. 7A, two dummy lines CDUM are located at the top of the GSL region, wherein the dummy lines CDUM may be located between the normal word line WL and the upper ground select line CGSL. In addition, in FIG. 7B, dummy lines CDUM are located at the bottom of the GSL region and located between the ground select lines CGSL. As an example, one dummy line CDUM is located between the lower ground select line CGSL and the normal ground select line GSL, while two dummy lines CDUM are located continuously between the ground select lines CGSL. In addition, in FIG. 7C, each of the plurality of dummy lines CDUM is located between the ground select lines CGSL within the GSL region. As an example, three dummy lines CDUM are discontinuously arranged.

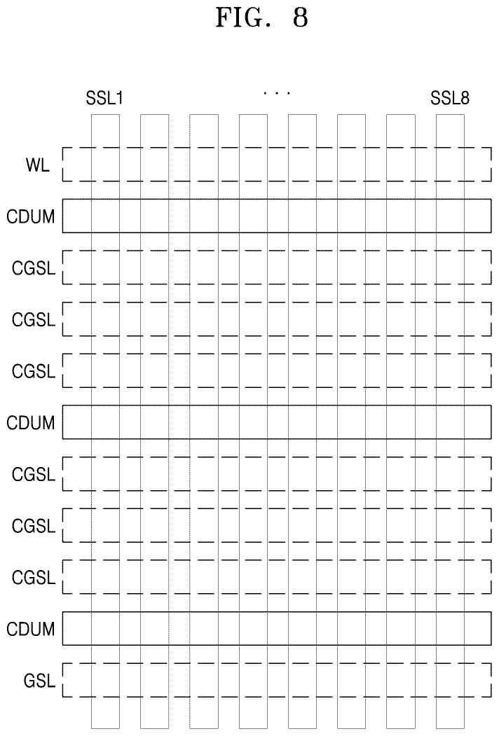

In FIG. 8, the GSL region includes a dummy line CDUM located at the top of the GSL region, a dummy line CDUM located at the bottom of the GSL region, and a dummy line CDUM located between the ground select lines CGSL. As an example, in FIG. 8, the GSL region includes one dummy line CDUM located between the normal word line WL and the upper ground select line CGSL, one dummy line CDUM located between the ground select lines CGSL, and one dummy line CDUM located between the lower ground select line CGSL and the normal ground select line GSL.

The cell blocks shown with reference to FIGS. 6A to 8 represent various examples of various arrangements of dummy lines. The implementation examples of cell blocks according to some embodiments are not necessarily limited to the structures shown with reference to FIGS. 6A to 8. That is, according to some embodiments, a location where dummy lines are arranged may be selected from among various locations in the GSL region. In addition, one or more dummy lines may be arranged at the selected location.

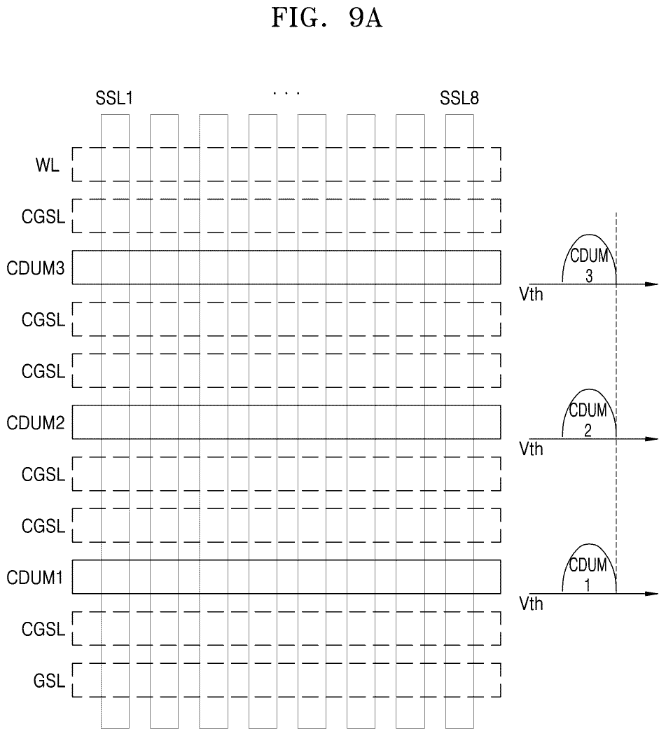

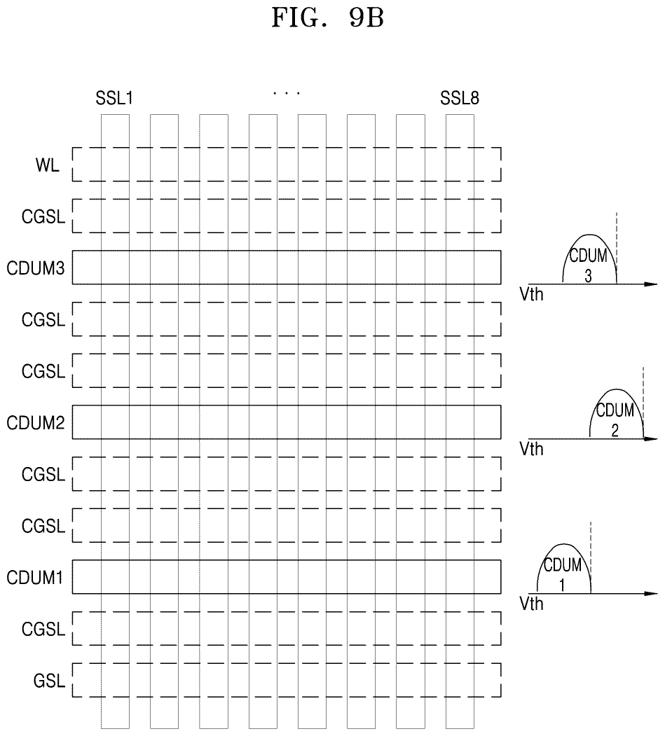

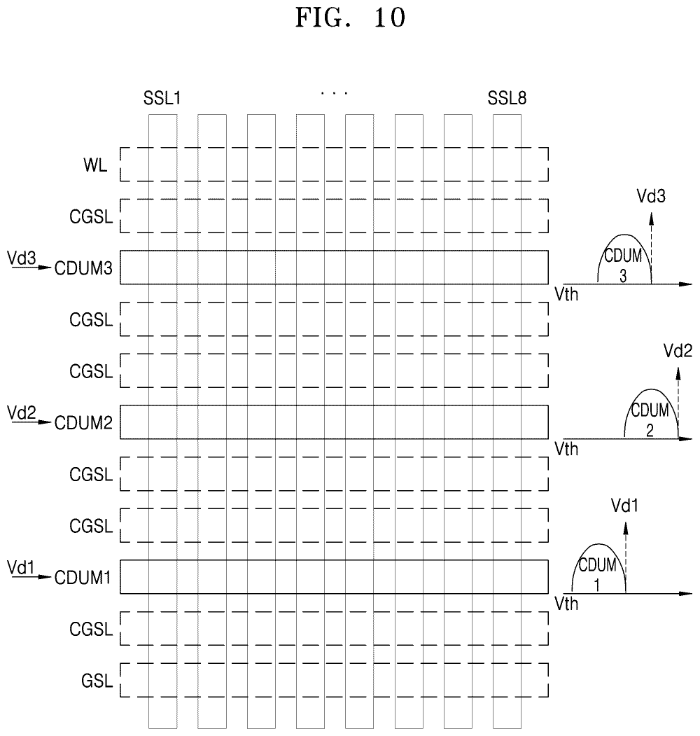

FIGS. 9A to 10 are diagrams showing the threshold voltage distribution and the voltage level of a dummy line. In FIGS. 9A to 10, among the dummy lines, a first dummy line CDUM1 is located at the bottom of the cell block in the vertical NAND structure, a second dummy line CDUM2 is located above the first dummy line CDUM1, and a third dummy line CDUM3 is located above the second dummy line CDUM2. A plurality of dummy cells may be connected to each of the first to third dummy lines CDUM1 to CDUM3, wherein each of the dummy cells may be programmed to a certain threshold voltage. Accordingly, each dummy line (or dummy cells connected to the dummy line) may have a threshold voltage distribution.

Each of the first to third dummy lines CDUM1 to CDUM3 may be arranged at any position within the GSL region. As an example, each of the first to third dummy lines CDUM1 to CDUM3 is located between the ground select lines CGSL on which coding is performed. In FIG. 9A, the threshold voltage distributions of the first to third dummy lines CDUM1 to CDUM3 have the same level. When the ground select transistors connected to the ground select line CGSL are programmed with the first threshold voltage and the second threshold voltage, the threshold voltage of the dummy cells may have a level between the first threshold voltage and the second threshold voltage.

Referring to FIG. 9B, the first to third dummy lines CDUM1 to CDUM3 may have different threshold voltage distributions. In FIG. 9B, the threshold voltage distribution of the third dummy line CDUM3 has a greater level than the threshold voltage distribution of the first dummy line CDUM1, and the threshold voltage distribution of the second dummy line CDUM2 has a greater level than the threshold voltage distribution of the third dummy line CDUM3.

The threshold voltage distribution of each of the first to third dummy lines CDUM1 to CDUM3 may have a level between the first threshold voltage and the second threshold voltage. In an embodiment, while the first to third dummy lines CDUM1 to CDUM3 have different threshold voltage distributions, the threshold voltage distribution of each dummy line may be programmed to have an arbitrary level. Alternatively, in an embodiment, the threshold voltage distribution of each dummy line may be set in relation to the threshold voltage distribution of at least one adjacent line. The threshold voltage distribution of the ground select line CGSL adjacent to the first dummy line CDUM1, the threshold voltage distribution of the ground select line CGSL adjacent to the second dummy line CDUM2, and the threshold voltage distribution of the ground select line CGSL adjacent to the third dummy line CDUM3 may be different. As an example, the level of the threshold voltage distribution of each dummy line may increase or decrease depending on the threshold voltage distribution of the adjacent ground select line CGSL.

As an example, when the number of ground select transistors programmed to a first threshold voltage having a low level is relatively large, among the ground select transistors connected to the ground select line CGSL adjacent to the first dummy line CDUM1, the threshold voltage distribution of the first dummy line CDUM1 may have a level less than the threshold voltage distribution of the other dummy lines. On the other hand, when the number of ground select transistors programmed to a second threshold voltage having a high level is relatively large, among the ground select transistors connected to the ground select line CGSL adjacent to the second dummy line CDUM2, the threshold voltage distribution of the second dummy line CDUM2 may have a level greater than the threshold voltage distribution of the first dummy line CDUM1.

In an embodiment shown in FIG. 9B, each dummy line is located between the ground select lines CGSL. However, when a dummy line is adjacent to the normal word line WL, the threshold voltage distribution of the dummy line may be set considering the threshold voltage distribution of the normal word line WL. In addition, when a dummy line is adjacent to the normal ground select line GSL, the threshold voltage distribution of the dummy line may be set considering the threshold voltage distribution of the normal ground select line GSL.

FIG. 10 shows an example of the dummy line voltage level provided to the dummy lines in a memory operation, such as data read operation, when the dummy lines have the threshold voltage distributions as shown in FIG. 9B. For example, in the memory operation, the dummy cells may be turned on as a pass voltage is applied to the dummy cells.

In an embodiment, as shown in FIG. 10, as the threshold voltage distribution is different for each dummy line, dummy line voltages having different levels may be provided for each dummy line in the memory operation. For example, a third dummy line voltage Vd3 provided to the third dummy line CDUM3 may have a greater level than a first dummy line voltage Vd1. Additionally, a second dummy line voltage Vd2 provided to the second dummy line CDUM2 may have a greater level than the first dummy line voltage Vd1 and the third dummy line voltage Vd3.

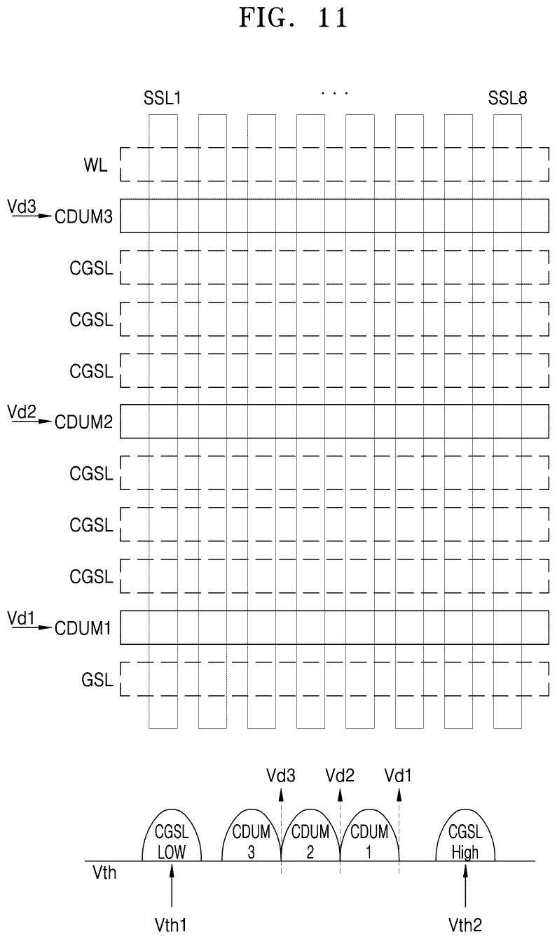

FIG. 11 is a diagram showing the threshold voltage distribution of a dummy line according to an embodiment. In FIG. 11, the GSL region includes first to third dummy lines CDUM1 to CDUM3. The first dummy line CDUM1 is adjacent to the normal ground select line GSL, the second dummy line CDUM2 is located between the ground select lines CGSL, and the third dummy line CDUM3 is located adjacent to the normal word line WL.

Each of the memory cells storing data may store more than 2 bits of information. In this case, the memory cells connected to the normal word line WL may have three or more threshold voltage distributions. In addition, as the ground select transistors connected to the ground select lines CGSL are programmed to the first threshold voltage Vth1 and the second threshold voltage Vth2, the ground select line CGSL may have a first distribution CGSL Low corresponding to the first threshold voltage Vth1 and a second distribution CGSL High corresponding to the second threshold voltage Vth2. In addition, as the ground select transistors connected to the normal ground select line GSL have an erase state or are programmed to a threshold voltage at a relatively low level, the normal ground select line GSL may have a single threshold voltage distribution.

In an embodiment, in FIG. 11, the level of the threshold voltage distribution of the first dummy line CDUM1 is greater than the level of the threshold voltage distribution of the second dummy line CDUM2. The level of the threshold voltage distribution of the second dummy line CDUM2 is greater than the level of the threshold voltage distribution of the third dummy line CDUM3. In addition, the program operation for dummy lines may be performed in various ways. As an example, although not shown in FIG. 11, the threshold voltage distributions of the first to third dummy lines CDUM1 to CDUM3 may have overlapping sections.

In addition, in the memory operation, such as data read operation, a first dummy line voltage Vd1 may be provided to the first dummy line CDUM1, a second dummy line voltage Vd2 may be provided to the second dummy line CDUM2, and a third dummy line voltage Vd3 may be provided to the third dummy line CDUM3, which extends immediately adjacent a normal word line WL associated with a lowermost row of nonvolatile memory cells, as shown. As the first to third dummy line voltages Vd1 to Vd3 correspond to the pass voltage, the dummy cells may be turned on. According to the levels of the threshold voltage distributions, the level of the first dummy line voltage Vd1 may be greater than the level of the second dummy line voltage Vd2, and the level of the second dummy line voltage Vd2 may be greater than the level of the third dummy line voltage Vd3.

Accordingly, as described hereinabove with respect to FIGS. 1, 5, and 10-11, for example, a memory device according to an embodiment of the inventive concept may include an array of non-volatile memory cells (e.g., flash memory cells) having a plurality of cell strings (e.g., NAND-type cell strings) therein, which are electrically coupled to a ground select line (GSL) region. In some of these embodiments, the GSL region may span eight (8) string select lines (e.g., SSL1 to SSL8), as shown, and may include a plurality of rows of “coded” ground select transistors, which have programmable threshold voltages and are electrically coupled to corresponding ground select lines (e.g., CGSL); however, other configurations are also possible in alternative embodiments. Advantageously, the GSL region may also include: (i) a first row of dummy memory cells that extend immediately adjacent a first one of the plurality of rows of ground select transistors and are programmed to have threshold voltages within a first threshold voltage distribution, and (ii) a second row of dummy memory cells that extend immediately adjacent a second one of the plurality of rows of ground select transistors and are programmed to have threshold voltages within a second threshold voltage distribution. According to some embodiments, a center threshold voltage within the second threshold distribution is spaced apart from a center threshold voltage within the first threshold voltage distribution, when measured on a threshold voltage scale.

Thus, as illustrated by the embodiment of FIG. 11, for example, the ground select transistors associated with each of the rows of coded ground select lines (CGSL) may be programmed to have a threshold voltage associated with an erased state (e.g., Vth1=CGSL Low) or a programmed state (e.g., Vth2=CGSL High), whereas the dummy memory cells associated with “coded” dummy lines (e.g., CDUM3, CDUM2, CDUM1) may be programmed to have “intermediate” threshold voltages within respective distributions: CDUM3, CDUM2 and CDUM1, which are higher than Vth1 and less than Vth2. Moreover, as shown by FIG. 10, a row of ground select transistors associated with a corresponding coded ground select line CGSL is sandwiched between a row of nonvolatile memory cells associated with a lowermost word line WL and a row of dummy memory cells associated with corresponding dummy word line CDUM3, whereas in FIG. 11, the row of dummy memory cells associated with dummy word line CDUM3 is sandwiched between the memory cells associated with the lowermost word line WL and a row of ground select transistors associated with a coded ground select line CGSL.

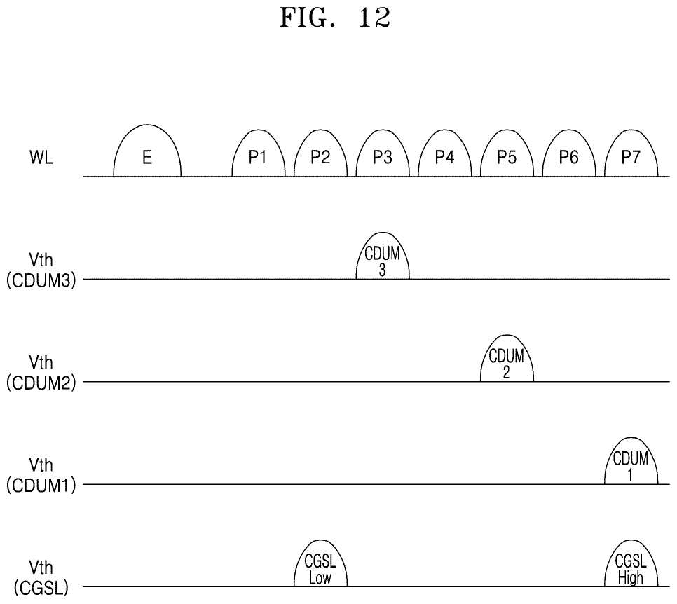

FIG. 12 is a diagram showing the threshold voltage distribution of various lines in a GSL region, according to another embodiment. The threshold voltage distributions shown in FIG. 12 illustrate the threshold voltage distributions of the first to third dummy lines CDUM1 to CDUM3 in the structure of the cell block shown in FIG. 11. In addition, as each of the memory cells storing data stores 3 bits of data, the memory cells may include 8 threshold voltage distributions, wherein the 8 threshold voltage distributions may correspond to the erase state E and the first to seventh program states P1 to P7.

As an example, the third dummy line CDUM3 may be located adjacent to the normal word line WL, wherein the threshold voltage distribution of the third dummy line CDUM3 may have a level between the erase state E and the seventh program state P7. For example, the threshold voltage distribution of the third dummy line CDUM3 may have a level similar to the third program state P3 or corresponds to the third program state P3 corresponding to the approximate average of the erase state E and the seventh program state P7.

The ground select line CGSL may have the first distribution CGSL Low and the second distribution CGSL High. The first distribution CGSL Low may correspond to or have a level similar to the second program state P2. The second distribution CGSL High may correspond to or have a level similar to the seventh program state P7. The threshold voltage distribution of the second dummy line CDUM2 located between the ground select lines CGSL may have a level between the second program state P2 and the seventh program state P7. For example, the threshold voltage distribution of the second dummy line CDUM2 may have a level similar to the fifth program state P5 or corresponds to the fifth program state P5 corresponding to the approximate average of the second program state P2 and the seventh program state P7.

The first dummy line CDUM1 may be located adjacent to the normal ground select line GSL or the common source line. In the memory operation, when a cell string is quickly electrically connected to the common source line, the threshold voltage distribution characteristics of a line adjacent to the common source line may deteriorate. In an embodiment, as the first dummy line CDUM1 is adjacent to the common source line, the level of the threshold voltage distribution of the first dummy line CDUM1 may be set high, thereby preventing the cell string from being quickly connected to the common source line. In an example, the threshold voltage distribution of the first dummy line CDUM1 may correspond to or have a level similar to the seventh program state P7 or may have a level higher than the seventh program state P7.

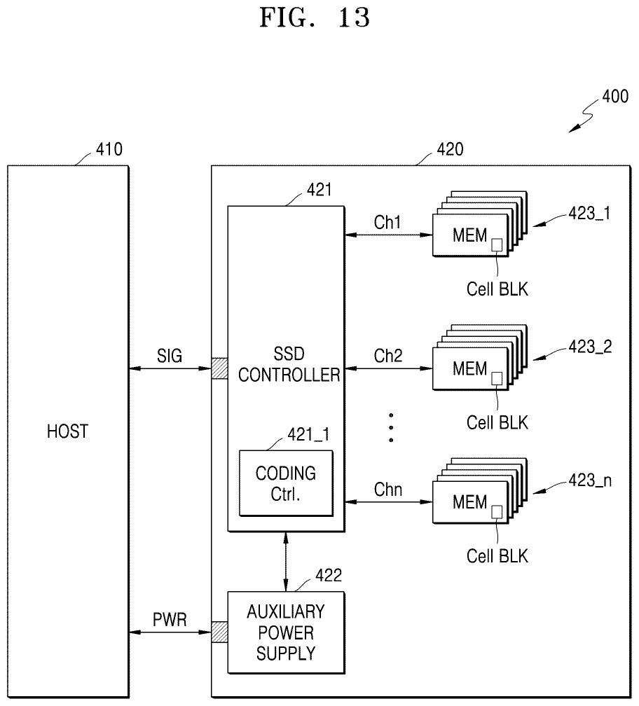

FIG. 13 is a block diagram of a solid state drive (SSD) system to which a memory device is applied, according to some embodiments.

Referring to FIG. 13, an SSD system 400 may include a host 410 and an SSD 420. The SSD 420 exchanges signals with the host 410 through a signal connector and receives power through a power connector. The SSD 420 may include an SSD controller 421, an auxiliary power device 422, and memory devices 423_1 to 423_n. The memory devices 423_1 to 423_n may include vertically stacked NAND flash memory devices. The SSD 420 may be implemented using the embodiments described above with reference to FIGS. 1 to 12. That is, each of the memory devices 423_1 to 423_n provided in the SSD 420 may include a plurality of cell blocks, wherein each cell block may include a GSL region, wherein the GSL region may include a plurality of ground select lines and one or more dummy lines. In addition, according to some embodiments, the dummy lines may be arranged in other numbers and positions within the GSL region, and dummy cells connected to the dummy lines may be programmed with threshold voltages according to some embodiments.

As an implementation example, the SSD controller 421 may include a coding controller 421_1, and each of the memory devices 423_1 to 423_n may store GSL control information (not shown). The GSL control information may be provided to the SSD controller 421. Based on the control by the coding controller 421_1, the SSD controller 421 may control the program operation for the SSD 420 so that various lines provided in the GSL region have a certain threshold voltage distribution.

While the inventive concept has been particularly shown and described with reference to embodiments thereof, it will be understood that various changes in form and details may be made therein without departing from the spirit and scope of the following claims.

1.-10. (canceled)

11. A memory device comprising:
a memory cell array comprising a cell block comprising a plurality of cell strings, wherein the cell block comprises a ground select line (GSL) region to electrically separate the plurality of cell strings; and
control logic for controlling program and read operations for the memory cell array,
wherein the GSL region comprises:
a plurality of ground select lines where a plurality of ground select transistors are connected and threshold voltages of the plurality of ground select transistors are programmed based on coding; and
first and second dummy lines each arranged adjacent to at least one ground select line,
wherein the threshold voltage distribution of the dummy cells connected to the first dummy line is different from the threshold voltage distribution of the dummy cells connected to the second dummy line.

12. The memory device of claim 11, wherein the first dummy line is arranged adjacent to a common source line, and the second dummy line is arranged adjacent to a normal word line where data is programmed.

13. The memory device of claim 11, wherein the first and second dummy lines are arranged consecutively and adjacent to a common source line.

14. The memory device of claim 11, wherein the first and second dummy lines are arranged consecutively and adjacent to a normal word line where data is programmed.

15. The memory device of claim 11, wherein the first dummy line is arranged adjacent to a common source line or a normal word line where data is programmed, and the second dummy line is arranged between the plurality of ground select lines.

16. The memory device of claim 11, wherein the GSL region further comprises at least one third dummy line, and the threshold voltage distribution of dummy cells connected to the third dummy line is different from the threshold voltage distribution of dummy cells connected to the first and second dummy lines.

17. The memory device of claim 16, wherein the first dummy line is arranged adjacent to a common source line, the second dummy line is arranged between the plurality of ground select lines, and the third dummy line is arranged adjacent to a normal word line where data is programmed.

18. The memory device of claim 17, wherein the threshold voltage distribution of the dummy cells connected to the first dummy line has a greater level than the threshold voltage distribution of the dummy cells connected to the second dummy line, and the threshold voltage distribution of the dummy cells connected to the second dummy line has a greater level than the threshold voltage distribution of the dummy cells connected to the third dummy line.

19. The memory device of claim 11, wherein, during a memory operation for the cell block, a first dummy line voltage is applied to the first dummy line and a second dummy line voltage is applied to the second dummy line, wherein the first dummy line voltage and the second dummy line voltage have different levels.

20. The memory device of claim 11, wherein some of the ground select transistors are programmed to a first threshold voltage, and the other ground select transistors are programmed to a second threshold voltage greater than the first threshold voltage, and
each of the dummy cells connected to the first and second dummy lines is programmed to a level between the first threshold voltage and the second threshold voltage.

21. The memory device of claim 11, wherein the cell block has a vertical NAND structure and the first dummy line is arranged below the second dummy line in the GSL region, and
the threshold voltage distribution of dummy cells connected to the first dummy line has a greater level than the threshold voltage distribution of dummy cells connected to the second dummy line.

22. A memory device having a vertical structure, the memory device comprising:
a memory cell array comprising a cell block comprising a plurality of cell strings, wherein the cell block comprises a common source line, a ground select line (GSL) region for electrically separating the plurality of cell strings, and normal word lines to which memory cells where data is programmed are connected, which are sequentially arranged in a vertical direction; and
control logic for controlling program and read operations for the memory cell array,
wherein the GSL region comprises:
a plurality of ground select lines, each of which is connected to a plurality of ground select transistors, wherein the plurality of ground select transistors are programmed to a first threshold voltage distribution and a second threshold voltage distribution; and
a plurality of dummy lines, each of which is connected to a plurality of dummy cells, wherein the plurality of dummy cells have one threshold voltage distribution, and
the threshold voltage distribution of dummy cells connected to some dummy lines and the threshold voltage distribution of dummy cells connected to the other dummy lines have different levels.

23. The memory device of claim 22, wherein the plurality of dummy lines comprise a first dummy line arranged adjacent to the common source line and a second dummy line arranged adjacent to the normal word lines, and
the threshold voltage distribution of dummy cells connected to the first dummy line has a different level from the threshold voltage distribution of dummy cells connected to the second dummy line.

24. The memory device of claim 22, wherein the plurality of dummy lines comprise a first dummy line arranged adjacent to the common source line or the normal word lines and a second dummy line arranged between the plurality of ground select lines, and
the threshold voltage distribution of dummy cells connected to the first dummy line has a different level from the threshold voltage distribution of dummy cells connected to the second dummy line.

25. The memory device of claim 22, wherein the plurality of dummy lines comprise a first dummy line arranged between the plurality of ground select lines and a second dummy line arranged between the plurality of ground select lines and located above the first dummy line, and
the threshold voltage distribution of dummy cells connected to the first dummy line has a different level from the threshold voltage distribution of dummy cells connected to the second dummy line.

26. The memory device of claim 22, wherein the plurality of dummy lines comprise a first dummy line arranged adjacent to the common source line, a second dummy line arranged between the plurality of ground select lines, and a third dummy line arranged adjacent to the normal word lines, and
the threshold voltage distributions of dummy cells connected to the first to third dummy lines have different levels.

27. A memory device comprising:
A memory cell array comprising a cell block comprising a plurality of cell strings, wherein the cell block comprises a common source line, a ground select line (GSL) region for electrically separating the plurality of cell strings, and normal word lines to which memory cells where data is programmed are connected, which are sequentially arranged in a vertical direction; and
control logic for controlling program and read operations for the memory cell array,
wherein the GSL region comprises:
a plurality of ground select lines where a plurality of ground select transistors are connected and threshold voltages of the plurality of ground select transistors are programmed based on coding; and
at least one first dummy line arranged at the bottom of the GSL region and adjacent to the common source line;
at least one second dummy line arranged between the plurality of ground select lines; and
at least one third dummy line arranged at the top of the GSL region and adjacent to the normal word lines.

28. The memory device of claim 27, wherein the threshold voltage distribution of dummy cells connected to the first dummy line has a greater level than the threshold voltage distribution of dummy cells connected to the second dummy line, and the threshold voltage distribution of the dummy cells connected to the second dummy line has a greater level than the threshold voltage distribution of dummy cells connected to the third dummy line.

29. The memory device of claim 28, wherein the cell block further comprises at least one normal ground select line arranged between the GSL region and the common source line, and the normal ground select line has a certain threshold voltage distribution and is arranged between the first dummy line and the common source line.

30. The memory device of claim 27, wherein the at least one second dummy line comprises a plurality of second dummy lines arranged between the ground select transistors, and
the threshold voltage distribution of some of the plurality of second dummy lines and the threshold voltage distribution of the other second dummy lines have different levels.

31. (canceled)
